(19) United States
(12) Patent Application Publication
(10) Pub. No.: US 2017/0346473 A1
(43) Pub. Date: Nov. 30, 2017

(54) DIFFERENTIAL COMPARATOR

(71) Applicant: NORDIC SEMICONDUCTOR ASA, Trondheim (NO)

(72) Inventors: Ola BRUSET, Trondheim (NO); Phil CORBISHLEY, Trondheim (NO)

(73) Assignee: NORDIC SEMICONDUCTOR ASA, Trondheim (NO)

(21) Appl. No.: 15/536,246

(22) PCT Filed: Dec. 14, 2015
(86) PCT No.: PCT/GB2015/053974

§ 371 Date: Jun. 15, 2017

(30) Foreign Application Priority Data
Dec. 15, 2014 (GB) 1422276.4

(51) Int. Cl. H03K 5/24; H04B 1/16; H03G 3/30

(52) U.S. Cl. CPC H03K 5/2481; H03G 3/3036; H04B 1/16

(57) ABSTRACT

A differential comparator has a first input and a second input comprises:
first and second transistors arranged as a differential pair connected to the first and second inputs respectively; and
a constant current arrangement disposed between said differential pair and a first supply rail;
   wherein a first path between the first transistor and the constant current arrangement has a different resistance to a second path between the second transistor and the constant current arrangement.

Also disclosed is a radio receiver employing such a differential comparator.

This invention relates to improvements in differential comparator circuits, particularly those employed on integrated circuits.

A differential comparator is a circuit element commonly used to measure signal levels in a circuit to determine when a difference between two signal levels exceeds a threshold. Conventionally it comprises a differential to single-ended amplifier and a voltage reference as the inputs to a high gain amplifier, such as an operational amplifier. An example of a known circuit arrangement is given in “MOS operational amplifier design-a tutorial overview”, IEEE Journal of Solid-State Circuits, Volume 17, Issue: 6, pages 969-982.

The present invention aims to improve upon the known circuit arrangements and provides a differential comparator having a first input and a second input and comprising:
first and second transistors arranged as a differential pair connected to the first and second inputs respectively; and
a constant current arrangement disposed between said differential pair and a first supply rail;
   wherein a first path between the first transistor and the constant current arrangement has a different resistance to a second path between the second transistor and the constant current arrangement.

Thus it will be seen by those skilled in the art that in accordance with the invention a deliberate mismatch is introduced between the transistors of the differential pair. This provides the desired function of a differential comparator but since only a single differential pair is required, the Applicant has found that this arrangement uses power more efficiently than conventional circuits which means that it can be operated at higher frequencies than known arrangements without a commensurate increase in the power used. It also requires a smaller area on an integrated circuit layout which is beneficial from a cost-saving point of view.

The first and second transistors may be of any suitable type but in a set of embodiments comprise field effect transistors, preferably metal oxide semiconductor field effect transistors (MOSFETs). The transistors are preferably identical, although this is not essential in view of the mismatch described above.

A differential pair usually drives a load. This could comprise a passive load such as a fixed resistor. However, in a set of embodiments an active load is provided between said differential pair and a second supply rail. The active load may comprise third and fourth transistors feeding said respective first and second transistors. Said third and fourth transistors are preferably field effect transistors, preferably metal oxide semiconductor field effect transistors (MOSFETs). In a set of embodiments the gate/base of one of said third and fourth transistors is connected to the drain/emitter thereof. The output of the comparator may be taken from the drain/emitter of the other of the third and fourth transistors. The active load could comprise a simple current mirror, but in other embodiments further circuitry, known per se, could be provided to introduce hysteresis and/or to give a faster switching time.

The first and second paths may each comprise one or more resistors to give said different resistance. Where one or more resistors is provided in each of the first and second paths, their respective resistances should have different nominal values—i.e. they should differ by more than would be expected from the inherent tolerance in the values of identical nominal resistances. In a set of embodiments one of said first and second paths comprises a resistor whilst the other does not.

The constant current arrangement could be provided in a number of ways. For example it could simply comprise a transistor or a cascaded pair of transistors. In preferred embodiments a single constant current source is provided which is common to the first and second paths. However this is not essential and separate constant current sources could be provided in the first and second paths respectively. These may provide the same current as one another or different currents.

Embodiments of the invention are particularly suitable for use in level detectors, particularly level detectors within radio receiver circuitry. This advantageously provides such a radio receiver with the capability to measure the level of a received signal and adjust the gain of components on the signal path so as to prevent clipping. Thus when viewed from a second aspect, the invention provides a radio receiver comprising:
a channel filter for attenuating components of a received radio signal that lie outside a particular channel;
a level detector located on the same signal path as the channel filter, wherein said level detector comprises a differential comparator having a first input and a second input and comprising:
   first and second transistors arranged as a differential pair connected to the first and second inputs respectively; and
   a constant current arrangement disposed between said differential pair and a first supply rail;
   wherein a first path between the first transistor and the constant current arrangement has a different resistance to a second path between the second transistor and the constant current arrangement; and
an automatic gain control system arranged to receive level-detection information from the level detectors, and to use the received level-detection information to adjust the gain of one or more gain-controlling systems in the radio receiver.

A particular embodiment of the invention will now be described, by way of example only, with reference to the accompanying drawings in which:

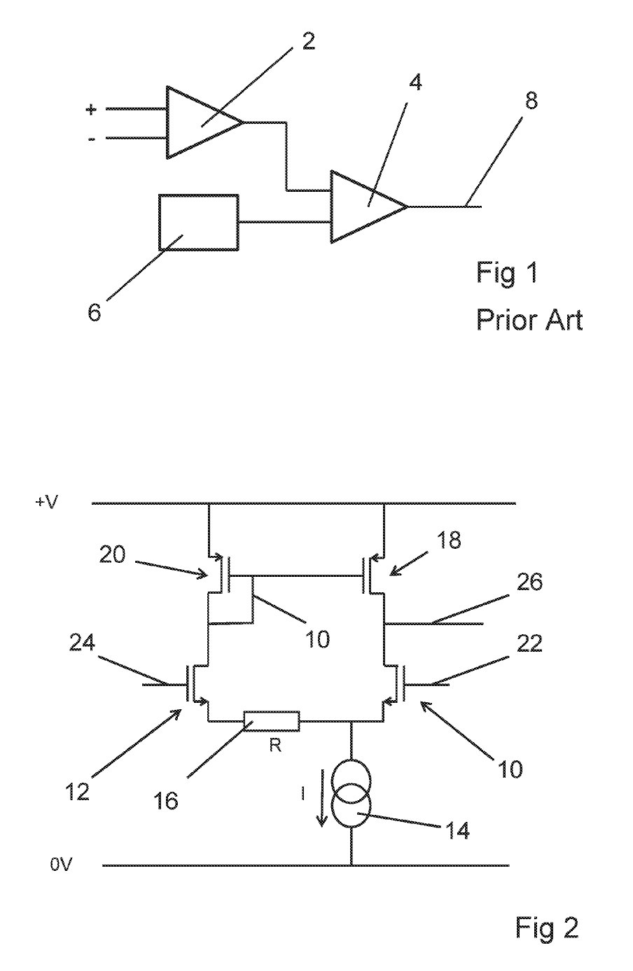

FIG. 1 is a diagrammatic representation of a prior art differential comparator arrangement;

FIG. 2 is a schematic circuit diagram of a comparator embodying the present invention; and

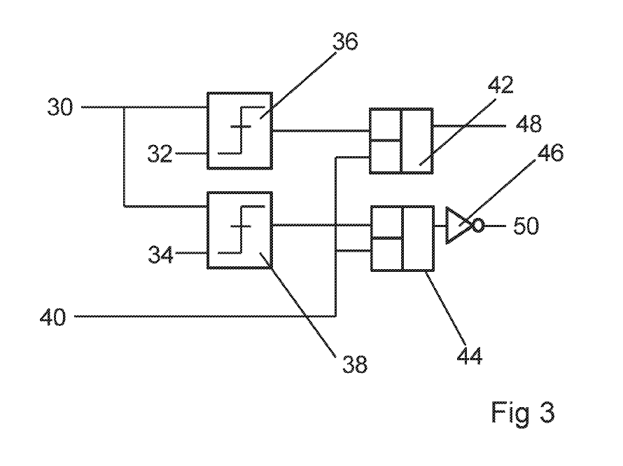

FIG. 3 is a diagrammatic representation of an exemplary implementation of the comparator of FIG. 2

FIG. 1 illustrates a conventional differential comparator. The two signals to be compared are fed into the + and − inputs of a differential amplifier 2. The output signal from the differential amplifier 2 equals the difference of the voltages on the + and − input terminals multiplied by a voltage gain Av, which can be higher or lower than unity, plus optionally a common mode voltage V_{CM}. The aforementioned output of the differential amplifier 2 provides one of the inputs to a high gain comparator 4. The other input to the comparator 4 is provided by a fixed voltage reference 6. The comparator 4 is typically set up so that its output 8 saturates high if its positive input (provided by the differential amplifier 2) is higher than its negative input (provided by the voltage reference 6) or is low otherwise. Thus in use if the difference between the + and − inputs of the differential amplifier is greater than a predetermined amount, the overall output 8 is high, whereas if the difference is less than this amount, the output 8 is low.

This circuit has many uses but the Applicant has appreciated that it is not optimised for some circumstances.

FIG. 2 shows an exemplary embodiment of the present invention. The circuit comprises a differential pair of Metal Oxide Semiconductor Field Effect Transistors (MOSFETs) 10, 12. The drain lead of one of the MOSFETs 10 is connected directly to a constant current source 14 disposed between the MOSFET 10 and the 0V rail. The drain lead of the other MOSFET 12 is also connected to the constant current source 14 but via a resistor 16 having a value R.

The source leads of the two MOSFETs 10, 12 are connected to the respective source leads of third and fourth MOSFETs 18, 20 which form a current mirror arrangement. The gate leads of the third and fourth MOSFETs 18, 20 are connected together and to the drain lead of the fourth 20. The source leads of the third and fourth MOSFETs are connected to the the voltage supply rail +V.

The inputs to the circuit 22, 24 are connected to the respective gate leads of the differential transistor pair 10, 12. As shown the gate lead to the first MOSFET 10 provides the negative input and the gate lead to the second MOSFET 12 provides the positive input The output of the circuit 26 is taken from the common source lead junction of the first and third MOSFETs 10, 28.

Operation of the circuit will now be described. If the same voltage level is applied to the two inputs 22, 24, there will be a voltage drop across the resistor 16. This gives a lower gate-source voltage across the second transistor 12 than across the first resistor 10 and so the source current of the second transistor 12 will be significantly reduced. This causes the voltage drop across the resistor 16 to reduce and the circuit thus eventually reaches equilibrium. Because the current in the current source 14 is constant, the reduction in current through the second transistor 12 will lead to a similar increase in current through the first transistor 10. This causes the output 26 to go low.

Similarly if the positive input 24 is only slightly higher than the negative input 22, dissimilar currents will flow and the output 26 will remain low. The switch point occurs when equal currents flow through both of the input transistors 10, 12—each being half the value, I of the current generated by the constant current source 14. At the switch point the voltage drop V_{SW} across the resistor 16 is therefore:

V_{SW}=0.5 IR

Thus for a given value, I, of the constant current source, the resistance value, R, of the resistor 16 determines the voltage differential between the input 22, 24 which will trigger the comparator. When equal currents flow through the input transistors 10, 12, the current mirror arrangement 18, 20 causes the output 26 to start to go high. When the current through the second transistor 12 exceeds the current through the first transistor 10 the output 26 will be high. This is because current from the second transistor 12 is mirrored through the third and fourth transistors 18, 20 of the curent mirror and added to the current from the first transistor 10. Because these currents have opposite directions and the amplitude of the current from the third transistor 18 is higher than the current from the first transistor 10, the output signal will be pulled high.

Taking a specific example, if the constant current generator 14 provides a current I=10 μA and the resistor has a value of 63 kΩ, the voltage drop at the switch point V_{SW}=0.5×0.00001×63000=315 mV.

Although the arrangement shown in FIG. 2 may have a lower accuracy than conventional differential comparator circuit arrangements—for example of the order of 20% compared to an accuracy of 1 to 5%, this is adequate in many applications. As an example, the Applicant has appreciated it is advantageous to provide a radio receiver with an Automatic Gain Control (AGC) loop which comprises a comparator as described herein. The purpose of this is to adjust the signal gain in the receiver to avoid saturation in the presence of strong signals, while still maintaining excellent noise performance in the presence of weak signals. This way, a dynamic range of the order of 100 dB can be achieved. For such a large gain range it is often impractical to have smaller gain steps than 3 dB, and an absolutely accuracy of 20% of the amplitude detector is then fully acceptable.

The embodiment described herein has been found however, to have a significantly lower power consumption than conventional alternatives. Whilst the comparator in this embodiment will typically have a similar current consumption to the comparator in a conventional circuit, the conventional circuit further requires a differential to single-ended amplifier. A common way to design this is by using two operational amplifiers with resistive feedback. Because of this, the differential to single-ended amplifier is most likely to be the dominant part of the power consumption in the conventional circuit. If it is assumed that a comparator consumes the same power as an operational amplifier, embodiment s of the invention may have a power consumption of around a third of the value for a conventional circuit. In practice the power consumption may be even lower as an operational amplifier with resistive feedback will generally consume more power than a comparator. Similarly embodiments of the invention can be implemented using less area on an integrated circuit. In some cases the greater power efficiency may also mean that the circuit acts faster and so can be used where a higher bandwidth is required.

FIG. 3 shows an exemplary implementation of the comparator of FIG. 2 in a level detector circuit employed in a radio receiver such as a packet-based digital radio receiver. In this arrangement an input signal voltage 30 is compared to two threshold voltages. A first differential comparator 36 of the type described with reference to FIG. 2 is fed with an upper reference voltage 32, and a second such differential comparator 38 is fed with a lower reference voltage 34. These differential comparators 36, 38 each produce an output signal that is fed to the reset input of a respective flip-flop 42, 44. If the input signal 30 has a higher voltage than a threshold voltage 32, 34, the respective differential comparator 36, 38 will output a logic high signal that sets the associated flip-flop 42, 44. The first flip-flop 42 produces a logic high on a ‘too-high’ output 48 if the input signal voltage 30 is greater than the upper reference voltage 32. The second flip-flop 44 produces a logic high on a ‘too-low’ output 50 by way of a logic invertor 46 if the input signal voltage 30 is less than the lower reference voltage 34.

It will be appreciated by those skilled in the art that the invention has been illustrated by describing a specific embodiment thereof but is not limited to that embodiment; many variations and modifications are possible within the scope of the attached claims. For example although a single resistor is shown in one of the paths between the differential pair and the constant current source, different resistors could be used in each path to achieve the same effect.

1. A differential comparator having a first input and a second input and comprising:
first and second transistors arranged as a differential pair connected to the first and second inputs respectively; and
a constant current circuit portion disposed between said differential pair and a first supply rail;
wherein a first path between the first transistor and the constant current circuit portion has a different resistance to a second path between the second transistor and the constant current circuit portion.

2. The differential comparator as claimed in claim 1 wherein the first and second transistors comprise field effect transistors.

3. The differential comparator as claimed in claim 1 wherein the first and second transistors are identical.

4. The differential comparator as claimed in claim 1, comprising an active load between said differential pair and a second supply rail.

5. The differential comparator as claimed in claim 4 wherein said active load comprises third and fourth transistors feeding said respective first and second transistors.

6. The differential comparator as claimed in claim 5 wherein the third and fourth transistors comprise field effect transistors.

7. The differential comparator as claimed in claim 5 wherein the gate/base of one of said third and fourth transistors is connected to the drain/emitter thereof.

8. The differential comparator as claimed in claim 7 comprising an output taken from the drain/emitter of the other of the third and fourth transistors.

9. The differential comparator as claimed in claim 4 wherein the active load comprises a current mirror.

10. The differential comparator as claimed in claim 1 wherein
one of said first and second paths comprises a resistor whilst the other does not.

11. The differential comparator as claimed in claim 1 comprising a single constant current source which is common to the first and second paths.

12. A radio receiver comprising a level detector including a differential comparator having a first input and a second input and comprising:
first and second transistors arranged as a differential pair connected to the first and second inputs respectively; and
a constant current circuit portion disposed between said differential pair and a first supply rail;
wherein a first path between the first transistor and the constant current circuit portion has a different resistance to a second path between the second transistor and the constant current arrangement.

13. A radio receiver comprising:
a channel filter for attenuating components of a received radio signal that lie outside a particular channel;
a level detector located on the same signal path as the channel filter, wherein said level detector comprises a differential comparator having a first input and a second input and comprising:
first and second transistors arranged as a differential pair connected to the first and second inputs respectively; and
a constant current circuit portion disposed between said differential pair and a first supply rail;
wherein a first path between the first transistor and the constant current circuit portion has a different resistance to a second path between the second transistor and the constant current circuit portion; and
an automatic gain control system arranged to receive level-detection information from the level detectors, and to use the received level-detection information to adjust the gain of one or more gain-controlling systems in the radio receiver.
